(19) United States
(12) Patent Application Publication
(10) Pub. No.: US 2009/0079520 A1
(43) Pub. Date: Mar. 26, 2009

(54) ACOUSTICALLY COUPLED RESONATORS HAVING RESONANT TRANSMISSION MINIMA

(75) Inventors: Tiberiu Jamneala, San Francisco, CA (US); Martha Small, Fort Collins, CO (US); Richard Ruby, Menlo Park, CA (US)

Correspondence Address: Kathy Manke;Avago Technologies Limited, 4380 Ziegler Road, Fort Collins, CO, 80525, US

(73) Assignee: Avago Technologies Wireless IP (Singapore) PTE. LTD., Denver, CO (US)

(21) Appl. No.: 11/858,237

(22) Filed: Sep. 20, 2007

(51) Int. Cl. H03H 9/58

(52) U.S. Cl. 333/189

(57) ABSTRACT

A bandpass filter includes input and output terminals, first and second acoustic resonators, and an acoustic coupling layer. The first acoustic resonator includes first and second electrodes, and a piezoelectric layer between the first and second electrodes. The first electrode of the first acoustic resonator is connected to the input terminal. The second acoustic resonator includes first and second electrodes, and a piezoelectric layer between the first and second electrodes. The acoustic coupling is provided between the second electrode of the first acoustic resonator and the first electrode of the second acoustic resonator. The output terminal is connected to the second electrode of the second acoustic resonator. A capacitor extends between the input terminal and the output terminal. The filter's frequency response includes at least two transmission zeros.

### BACKGROUND

There is an increasing demand for communication devices capable of operating across a variety of different frequency bands. For example, there is an increasing demand for cellular or mobile telephones that can operate in multiple frequency bands. In such devices, separate transmit and receive filters are in general employed for each transmit and receive frequency band. In practice, bulk acoustic wave (BAW) filters, surface acoustic wave (SAW) filters, thin film bulk acoustic resonator (FBAR) filters and coupled resonator filters (CRF) may be employed in appropriate applications.

A typical implementation of an acoustic resonator comprises a layer of piezoelectric material arranged between two metal electrodes. Common piezoelectric materials include, for example, aluminum nitride (AlN) and zinc oxide (ZnO).

FIG. 1 shows an exemplary resonator 10 which comprises a layer of piezoelectric material which will be referred to as piezo layer 12 below, and is located between a first electrode, or top electrode T, and a second electrode, or bottom electrode B. The designations top electrode and bottom electrode are just for definition purposes and do not represent any limitation with regard to the spatial arrangement and positioning of the acoustic resonator.

If an electric field is applied between first electrode T and second electrode B of acoustic resonator 10, the reciprocal or inverse piezoelectric effect will cause acoustic resonator 10 to mechanically expand or contract, the case of expansion or of contraction depending on the polarization of the piezoelectric material. This means that the opposite case applies if the electric field is inversely applied between the T and B electrodes. In the case of an alternating field, an acoustic wave is generated in piezo layer 12, and, depending on the implementation of acoustic resonator 10, this wave will propagate, for example, in parallel with the electric field, as a longitudinal wave, or, as a transversal wave, transverse to the electric field, and will be reflected, for example, at the interface of piezo layer 12. For longitudinal waves, whenever the thickness d of piezo layer 12 and of the top and bottom electrodes equals an integer multiple of half the wavelength λ of the acoustic waves, resonance states and/or acoustic resonance vibrations will occur. Because each acoustic material has a different propagation velocity for the acoustic wave the fundamental resonance frequency, i.e. the lowest resonance frequency F_{RES}, will then be inversely proportional to weighted sum of all thicknesses of the resonator layers.

The piezoelectric properties and, thus, also the resonance properties of an acoustic resonator depend on various factors, e.g. on the piezoelectric material, the production method, the polarization impressed upon the piezoelectric material during manufacturing, and the size of the crystals. As has been mentioned above, it is the resonance frequency in particular which depends on total thickness of the resonator.

FIG. 2 shows a model of a bulk acoustic wave (BAW) device or thin film bulk acoustic resonator (FBAR). The model of FIG. 2 is a modified Butterworth-Van Dyke model (MBVD) model. For a high quality resonator, the resistance values Rs, Ro, and Rm are small, in which case they can be neglected at the frequencies of interest. In that case, for simplification the device can be modeled by the series-resonant combination of Lm and Cm, in parallel with a capacitance Co. The frequency response of this model is a bandpass response, with frequencies below the passband being attenuated by the capacitors Cm and Co, and with frequencies above the passband being attenuated by the inductance Lm.

As noted above, acoustic resonators can be employed in electrical filters, and in particular in radio frequency (RF) and microwave filters. These resonators can be combined in various ways to produce a variety of filter configurations. One particular configuration is a coupled resonator filter (CRF) wherein a coupling layer combines the acoustic action of the two acoustic resonators, which leads to a bandpass filter transfer function.

In particular, as noted above, such filters are often employed in cellular or mobile telephones that can operate in multiple frequency bands. In such devices, it is important that a filter intended to pass one particular frequency band (“the passband”) should have a high level of attenuation at other nearby frequency bands which contain signals that should be rejected. Specifically, there may be one or more frequencies or frequency bands near the passband which contain signals at relatively high amplitudes that should be rejected by the filter. In such cases, it would be beneficial to be able to increase the filter's rejection characteristics at those particular frequencies or frequency bands, even if the rejection at other frequencies or frequency bands does not receive the same level of rejection.

What is needed, therefore, is an acoustic resonator filter structure having increased near-band rejection, and in particular exhibits increased rejection at specific desired frequencies. What is also needed is an acoustic resonator filter structure which can be designed to tune its attenuation characteristics to reject one or more desired frequencies or frequency ranges.

### SUMMARY

In an example embodiment, a signal processing device comprises: an input terminal adapted to receive an input signal; a first acoustic resonator having a first electrode, a second electrode, and a piezoelectric layer extending between the first and second electrodes of the first acoustic resonator, wherein the first electrode of the first acoustic resonator is connected to the input terminal; a second acoustic resonator having a first electrode, a second electrode, and a piezoelectric layer extending between the first and second electrodes of the second acoustic resonator; an acoustic coupling layer having a first side connected to the second electrode of the first acoustic resonator, and a second side opposite the first side connected to the first electrode of the second acoustic resonator, the acoustic coupling layer being adapted to couple acoustic energy from the first acoustic resonator to the second acoustic resonator; an output terminal connected to the second electrode of the second acoustic resonator; and a capacitor extending between the input terminal and the output terminal. A transmission path from the input terminal to the output terminal has a frequency response exhibiting a passband and a central passband frequency and at least two transmission zeros. The first transmission zero is at a frequency that is less than the central passband frequency and at least 10% of the central passband frequency, and the second transmission zero is at a frequency that is greater the central passband frequency and is no more than 1000% of the central passband frequency.

In another example embodiment, a radio frequency filter comprises: an input terminal; an output terminal; an acoustic coupling layer; a first acoustic resonator disposed between the input terminal and the acoustic coupling layer; a second acoustic resonator disposed between the acoustic coupling layer and the output terminal; and a capacitor extending between the input terminal and the output terminal.

In yet another example embodiment, a bandpass filter comprises a coupled resonator structure having a first acoustic resonator coupled to a second acoustic resonator by an acoustic coupling layer, the filter having a passband and a central passband frequency and at least two transmission zeros in its frequency response.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 shows an exemplary acoustic resonator.

FIG. 2 shows an electrical model of a bulk acoustic wave (BAW) or thin film bulk acoustic resonator (FBAR).

FIG. 3 shows two acoustically coupled acoustic resonators.

FIG. 4 shows a transmission frequency response of the acoustically coupled resonators of FIG. 3.

FIG. 5 shows one embodiment of a signal processing device including two acoustically coupled resonators.

FIG. 6 shows the equivalent electrical model of the signal processing device of FIG. 5.

FIG. 7 shows an ABCD matrix-descriptive equivalent of the model of FIG. 6.

FIG. 8 shows a transmission frequency response of the signal processing device of FIG. 5.

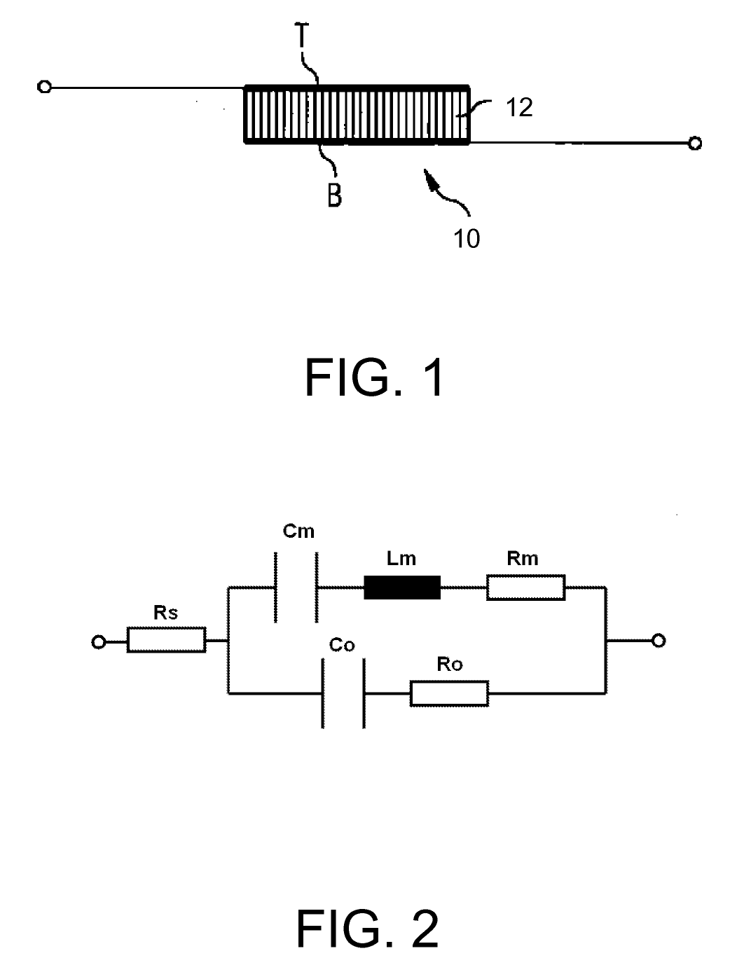

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

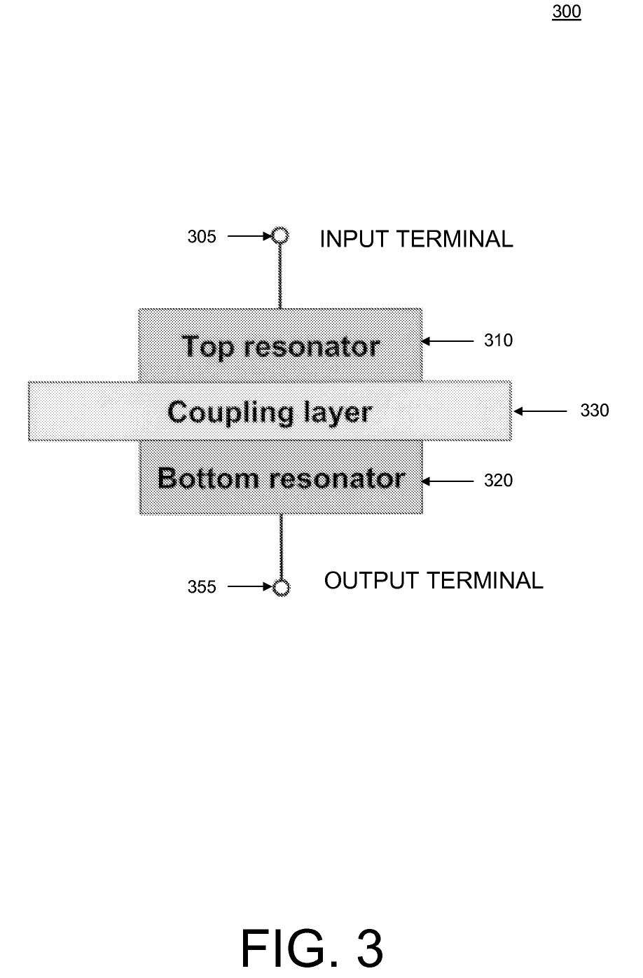

FIG. 3 shows a device 300 including two acoustically coupled acoustic resonators 310, 320 having an acoustic coupling layer 330 between them.

Device 300 may operate as a bandpass filter, receiving an input signal applied to the input terminal 305 connected to the first acoustic resonator 310, and providing a bandpass-filtered output signal at output terminal 355.

In one common application, a bandpass filter is employed in a cellular or mobile telephone. The mobile telephone may operate in one or more frequency bands. However at any given time, the mobile telephone may operate in the presence of a number of strong signals in nearby frequency bands. For proper operation of the mobile telephone, it is necessary for the bandpass filter to pass the signals in the frequency band on which the mobile telephone operates, while at the same time providing a high level of rejection of these signals on the nearby frequency bands.

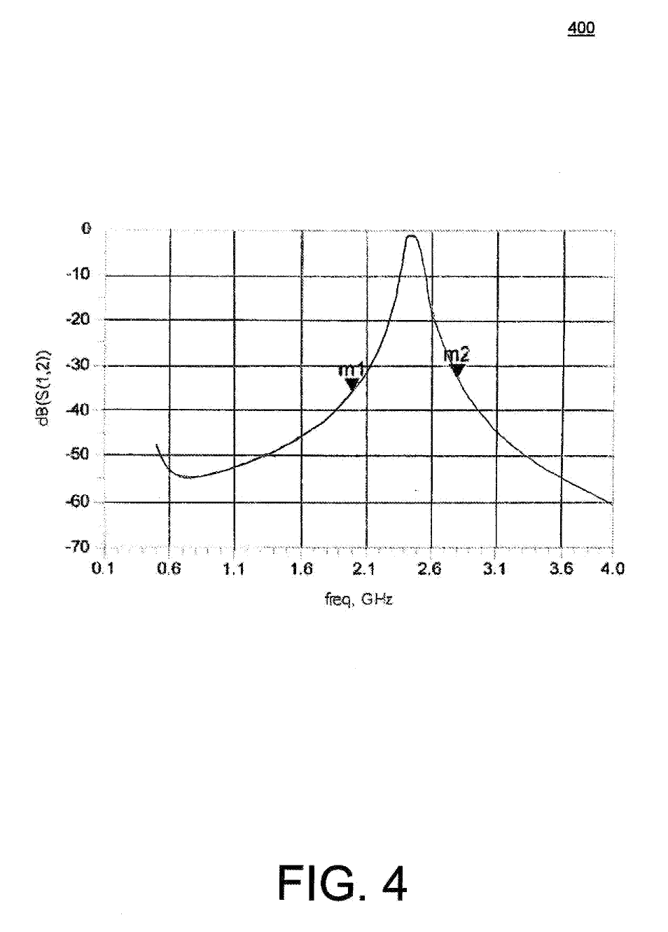

The arrangement shown in FIG. 3 is known in the art for use as a bandpass filter, but it suffers from inadequate near-band rejection for many applications, as explained with respect to FIG. 4.

For example, consider an application where it is desirable to pass signals in a frequency band centered around 2.4 GHz, while rejecting signals at frequencies near 2.0 GHz and/or 2.8 GHz. FIG. 4 shows a transmission frequency response 400 of an embodiment of device 300 that has been designed to have a central passband frequency of around 2.4 GHz. As can be seen, frequency response 400 provides about 36 dB of rejection at 2.0 GHz and only about 33 dB of rejection at 2.8 GHz. However, this level of near-band rejection is inadequate for many applications.

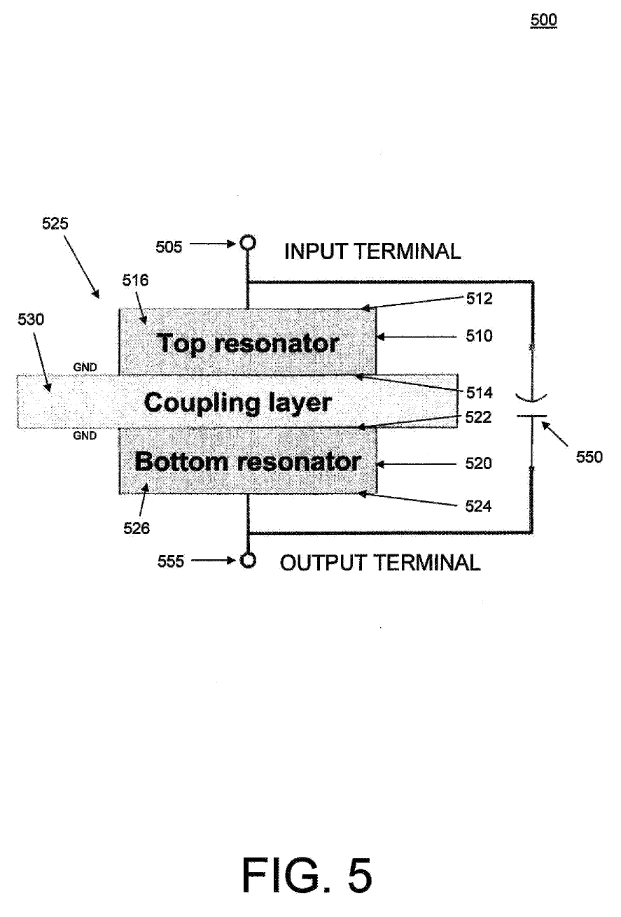

To address this shortcoming, FIG. 5 shows one embodiment of a signal processing device 500 that provides transmission zeroes (or localized transmission minima) which may be placed at desired frequencies in the frequency spectrum as will be explained in greater detail below.

Device 500 includes input terminal 505, output terminal 555, a coupled resonator filter (CRF) 525, and a capacitor 550. CRF 525 includes a first acoustic resonator 510, a second acoustic resonator 520, and acoustic coupling layer 530.

First resonator 510 includes a first electrode 512, a second electrode 514, and a piezoelectric layer 516 extending between first and second electrodes 512 and 514. First electrode 512 is connected to input terminal 505. In one embodiment, first resonator 510 is a thin film bulk acoustic resonator (FBAR). In one embodiment, first and second electrodes 512 and 514 are made of molybdenum, and piezoelectric layer 516 is made of aluminum nitride (AlN).

Second resonator 520 includes a first electrode 522, a second electrode 524, and a piezoelectric layer 526 extending between first and second electrodes 522 and 524. Second electrode 524 is connected to output terminal 555. In one embodiment, second resonator 520 is a thin film bulk acoustic resonator (FBAR). In one embodiment, first and second electrodes 522 and 524 are made of molybdenum, and piezoelectric layer 526 is made of aluminum nitride (AlN).

Acoustic coupling layer 530 is provided between first resonator 510 and second acoustic resonator 520. Acoustic coupling layer 530 has a first side connected to second electrode 514 of first acoustic resonator 510, and has a second side opposite the first side connected to first electrode 522 of second acoustic resonator 520. Acoustic coupling layer 530 couples acoustic energy from first acoustic resonator 510 to second acoustic resonator 520. To facilitate this coupling, the acoustic impedance of acoustic coupling layer 530 is less than the acoustic impedance of second electrode 514 of first acoustic resonator 510, and is also less than the acoustic impedance of first electrode 522 of second acoustic resonator 520. In one embodiment, acoustic coupling layer 530 comprises a low dielectric constant (“low-k”) silicon material layer. For example, at frequencies of interest, acoustic coupling layer may have an acoustic impedance of <5 megarayls, for example 2-3 megarayls. In contrast, second electrode 514 of first acoustic resonator 510, and first electrode 522 of second acoustic resonator 520 (each of which may made of molybdenum, for example), may have an acoustic impedance of 65 megarayls. The high ratio of acoustic impedances between acoustic resonator electrodes 514/522 and acoustic coupling layer 530 facilitates coupling of acoustic energy between acoustic resonators 510 and 520 by acoustic coupling layer 530.

Capacitor 550 extends between input terminal 505 and output terminal 555. In other words, capacitor 550 extends between first electrode 512 of first acoustic resonator 510, and second electrode 524 of second acoustic resonator 520. As will be explained in greater detail below, capacitor 550 can be selected to provide a pair of transmission zeroes (or localized transmission minima) in the transmission frequency response of device 500.

Of particular benefit, in some embodiments capacitor 550 is small enough that it can be implemented in the layout of the CRF 525 itself and thus does not require an external element.

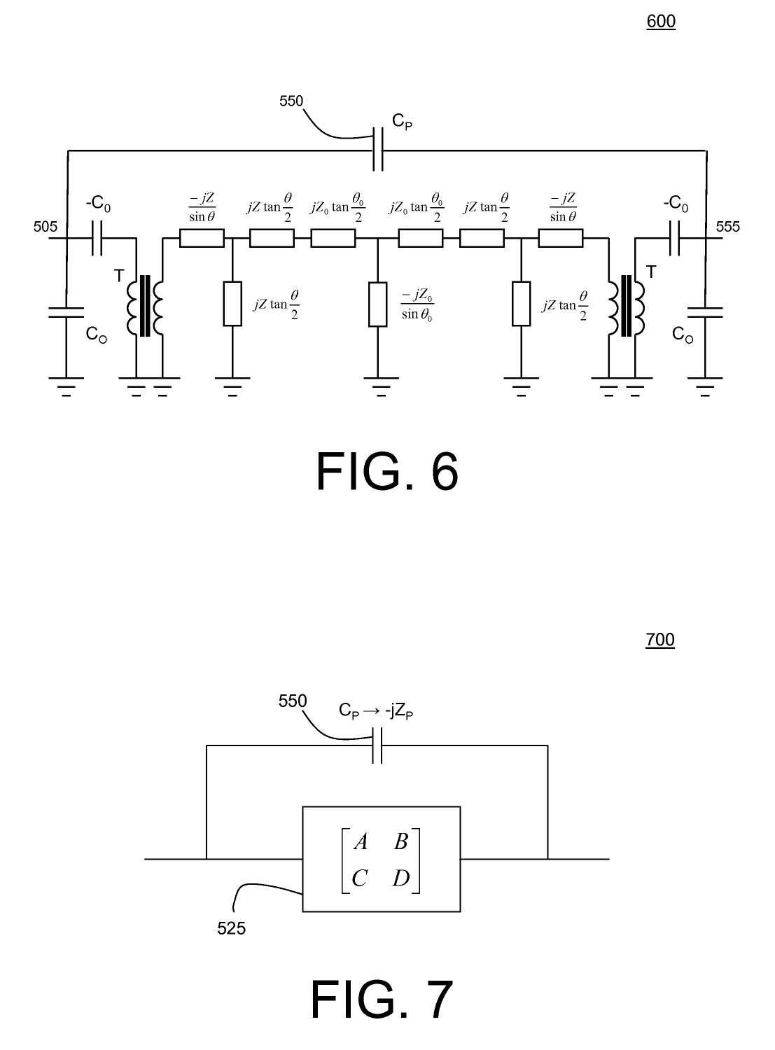

To better understand how the frequencies of the transmission zeros (or localized transmission minima) in the frequency response of signal processing device 500 are determined, FIG. 6 shows a detailed electrical model 600 of signal processing device 500. In the model of FIG. 6, a “thin-electrode” approximation is made for each of the acoustic resonators 510 and 520. Also, the device 500 is assumed to have a symmetric structure such that S₁₁=S₂₂.

In FIG. 6:
C₀ represents the parallel plate capacitance of each acoustic resonator;
z represents the acoustic impedance of the piezoelectric layer for each acoustic resonator;
z₀ represents the acoustic impedance of the acoustic coupling layer;
−jz_{c} represents the impedance of the parallel plate capacitance of each acoustic resonator at a frequency of interest;

$$T = \sqrt{( \frac{π`}{{Kt}^{2}} ) ( \frac{f}{{f}_{0}} ) ( \frac{{z}_{c}}{z} )} ,$$

where Kt²≅0.065 and f₀ is the central passband frequency of signal processing device 500;
θ and θ₀ represent the phase angles for the, piezoelectric layer 516/526, and the acoustic coupling layer 530, respectively.

θ and θ₀ can be calculated as follows:

$$\begin{matrix}θ = 2 π f \frac{d}{v} & ( 1 ) \\ {θ}_{0} = 2 π f \frac{{d}_{0}}{{v}_{0}} & ( 2 )\end{matrix}$$

where d and d₀ are the thicknesses of piezoelectric layer 516/526, and the acoustic coupling layer 530, respectively, and
where v and v₀ are the acoustic velocities of piezoelectric layer 516/526, and the acoustic coupling layer 530, respectively.

To facilitate the analysis of the electrical model of signal processing device 500, FIG. 7 shows a simplified mathematical equivalent 700 of the device 500. In FIG. 7, the signal processing device 500, in the absence of the capacitance Cp, is represented by the matrix

$$[ \begin{matrix}A & B \\ C & D\end{matrix} ] .$$

It can be shown that the condition for a zero to occur in the transmission frequency response of signal processing device 500 is defined by equation (1):

$${Z}_{P} = \frac{1}{ω {C}_{P}} = j B \qquad ( 3 )$$

Thus, if the B coefficient of the matrix

$$[ \begin{matrix}A & B \\ C & D\end{matrix} ]$$

is negative and imaginary, then equation (3) will produce physically realizable (positive) values and the transmission minima can occur. When certain simplifying assumptions are made, it can be shown that the frequencies F1 and F2 of the first and second transmission zeros can be calculated as:

$$\begin{matrix}F 1 = {f}_{0} - [ \frac{v}{2 π d} ] \sqrt{[ \frac{{C}_{0}}{{C}_{P}} ] [ \frac{{z}_{0}}{x} ] [ \frac{{Kt}^{2}}{π} ]} & ( 4 ) \\ F 2 = {f}_{0} + [ \frac{v}{2 π d} ] \sqrt{[ \frac{{C}_{0}}{{C}_{P}} ] [ \frac{{z}_{0}}{x} ] [ \frac{{Kt}^{2}}{π} ]} & ( 5 )\end{matrix}$$

Thus, from equations (4) and (5) it can be seen that by proper selection of various parameters of first and second acoustic resonators 510 and 520, acoustic coupling layer 530, and capacitor 530, it is possible to place transmission zeros F1 and F2 (which may in practice appear as localized transmission minima) in the frequency response of signal processing device 500 at desired frequencies. In particular, it can be seen from equations (4) and (5) that most material parameters are fixed and the rest (except for Cp) are determined by the passband requirements (bandwidth, center frequency, etc) of the filter. Thus, the two transmission zeros F1 and F2 are not independent, but rather they move together when the value Cp changes.

In operation, device 500 may function as a bandpass filter. In that case, second electrode 514 of first acoustic resonator 510, and first electrode 522 of second acoustic resonator 520 are each connected to ground as shown in FIG. 5. An input RF or microwave signal is applied to input terminal 505 connected to the first acoustic resonator 510, and a bandpass-filtered output signal is produced at output terminal 555 connected to second acoustic resonator 520.

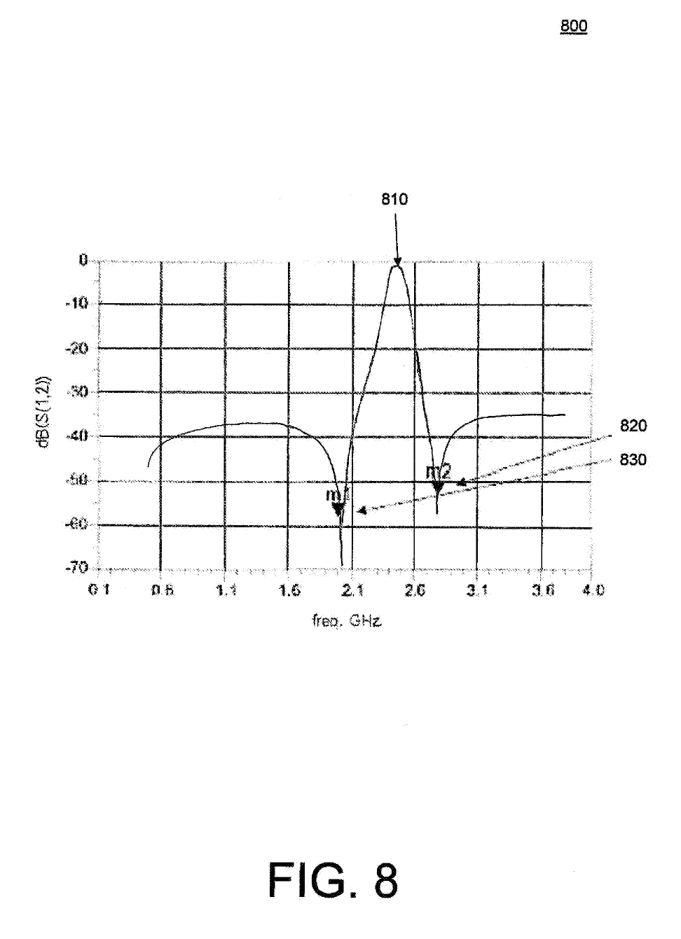

FIG. 8 shows a transmission frequency response 800 of one embodiment of signal processing device 500 of FIG. 5. In particular, FIG. 8 shows a transmission frequency response 800 of an embodiment of device 500 that has been designed to have a central passband frequency of around 2.4 GHz. As can be seen in FIG. 8, frequency response 800 has a passband characteristic and also includes two transmission zeroes 820 and 830 at 2.0 GHz and 2.8 GHZ, respectively. In this embodiment, capacitor 550 has a capacitance Cₚ of about 30 femtofarads such that, in conjunction with various parameters of acoustic resonators 510 and 520 and acoustic coupling layer 530 (e.g., thickness; acoustic impedance), the transmission zeros are produced at desired frequencies. As noted above, for such a small capacitance value, it is possible in one embodiment to realize the desired capacitance by appropriate design of the layout of CRF 525 without requiring a separate or discrete capacitor element.

In a particular embodiment, a first (lower frequency) transmission zero may be produced at a frequency that is less than the central passband frequency, and a second transmission zero may be produced at a frequency that is greater than the central passband frequency. In particular, it is often desirable to produce the “lower” transmission zero at a frequency that is at least 10% of the central passband frequency (thus, for example, excluding any transmission zero that may naturally occur at DC). It is also often desirable to produce the “upper” transmission zero at a frequency that is greater than 1000% of the central passband frequency (thus, for example, excluding any transmission zero that may theoretically occur at “infinite frequency”). So, for example, in a case where the central passband frequency is 2.0 GHz, then the frequency of the lower transmission zero in general should be greater than 200 MHz, and the frequency of the upper transmission zero in general should be less than 20 GHz. However these ranges are merely exemplary and not limiting.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. A signal processing device, comprising:
an input terminal adapted to receive an input signal;
a first acoustic resonator having a first electrode, a second electrode, and an acoustic propagation layer extending between the first and second electrodes of the first acoustic resonator, wherein the first electrode of the first acoustic resonator is connected to the input terminal;
a second acoustic resonator having a first electrode, a second electrode, and a piezoelectric layer extending between the first and second electrodes of the second acoustic resonator;
an acoustic coupling layer having a first side connected to the second electrode of the first acoustic resonator, and a second side opposite the first side connected to the first electrode of the second acoustic resonator, the acoustic coupling layer being adapted to couple acoustic energy from the first acoustic resonator to the second acoustic resonator;
an output terminal connected to the second electrode of the second acoustic resonator; and
a capacitor extending between the input terminal and the output terminal,
wherein a transmission path from the input terminal to the output terminal has a frequency response exhibiting a passband and a central passband frequency and at least two transmission zeros, the first transmission zero being at a frequency that is less than central passband frequency and at least 10% of the central passband frequency, and the second transmission zero being at a frequency that greater than central passband frequency and is no more than 1000% of the central passband frequency.

2. The device of claim 1, wherein the acoustic coupling layer has an acoustic impedance that is less than an acoustic impedance of the second electrode of the first acoustic resonator, and is also less than an acoustic impedance of the first electrode of the second acoustic resonator.

3. The device of claim 2, wherein a ratio of the acoustic impedance of the second electrode of the first acoustic resonator to the acoustic impedance of the acoustic coupling layer is greater than 10:1, and wherein a ratio of the acoustic impedance of the first electrode of the second acoustic resonator to an acoustic impedance of the acoustic coupling layer is also greater than 10:1.

4. The device of claim 1, wherein the capacitor has a value such that the frequency response of the transmission path between the input terminal and the output terminal exhibits transmission zeros at about 2.0 GHz and 2.8 GHz.

5. The device of claim 1, wherein the capacitor has a value of about 30 fF.

6. The device of claim 1, wherein the acoustic coupling layer comprises a silicon material having a low dielectric constant.

7. The device of claim 1, wherein the second electrode of the first acoustic resonator and the first electrode of the second acoustic resonator are each connected to ground.

8. A radio frequency filter, comprising:
an input terminal;
an output terminal;
an acoustic coupling layer;
a first acoustic resonator disposed between the input terminal and the acoustic coupling layer;
a second acoustic resonator disposed between the acoustic coupling layer and the output terminal; and
a capacitor extending between the input terminal and the output terminal.

9. The filter of claim 8, wherein the capacitor has a value such that a frequency response of a transmission path between the input terminal and the output terminal exhibits transmission zeros at about 2.0 GHz and 2.8 GHz.

10. The filter of claim 8, wherein the capacitor has a value of about 30 fF.

11. The filter of claim 8, wherein the acoustic coupling layer comprises a silicon material having a low dielectric constant.

12. The filter of claim 8, wherein an electrode of the first acoustic resonator and an electrode of the second acoustic resonator are each connected to ground.

13. A bandpass filter comprising a coupled resonator structure having a first acoustic resonator coupled to a second acoustic resonator by an acoustic coupling layer, the filter having a passband and a central passband frequency and at least two transmission zeros in its frequency response.

14. The filter of claim 13, further comprising a capacitance across the coupled resonator structure.

15. The filter of claim 14, wherein the capacitance has a value such that the two transmission zeros are located at about 2.0 GHz and 2.8 GHz.

16. The filter of claim 14, wherein the capacitance has a value of about 30 fF.

17. The filter of claim 13, wherein the acoustic coupling layer comprises a silicon material having a low dielectric constant.
